(19) United States
(12) Patent Application Publication
(10) Pub. No.: US 2013/0250528 A1
(43) Pub. Date: Sep. 26, 2013

(54) CIRCUIT MODULE

(71) Applicant: MURATA MANUFACTURING CO., LTD., Nagaokakyo-shi (JP)

(72) Inventor: Takayuki HORIBE, Nagaokakyo-shi (JP)

(73) Assignee: MURATA MANUFACTURING CO., LTD., Nagaokakyo-shi (JP)

(21) Appl. No.: 13/901,703

(22) Filed: May 24, 2013

Related U.S. Application Data
(63) Continuation of application No. PCT/JP2011/077388, filed on Nov. 28, 2011.

(30) Foreign Application Priority Data
Dec. 10, 2010 (JP) 2010-275584

(51) Int. Cl. H05K 9/00; H05K 1/18

(52) U.S. Cl. CPC H05K 9/00; H05K 1/18
USPC 361/748

(57) ABSTRACT

A circuit module provided with an auxiliary substrate includes a structure in which electronic components are mounted on a circuit substrate arranged at a bottom, an insulating resin covering the electronic components is defined so as to be higher than the electronic components, and the auxiliary substrate is arranged on the insulating resin. As a result, there has been a problem in that the height of the circuit module is increased. The circuit module is defined such that at least one of the electronic components is in contact with the auxiliary substrate.

### BACKGROUND OF THE INVENTION

1. Field of the Invention

The present invention relates to circuit modules having a configuration in which electronic components are mounted on a substrate.

2. Description of the Related Art

Examples of existing circuit modules include a circuit module 90 disclosed in Japanese Unexamined Patent Application Publication No. 9-130022, as illustrated in FIG. 6. In the circuit module 90, electronic components 92, 92, . . . are mounted on only one surface of a circuit substrate 91. An auxiliary substrate 97 is arranged parallel to the one surface of the circuit substrate 91 and the space between the circuit substrate 91 and the auxiliary substrate is filled with a synthetic resin 94, whereby the electronic components 92 are sealed.

With this configuration, in the circuit module 90, stress due to a difference in temperature coefficient of expansion between the insulating synthetic resin 94 and the circuit substrate 91 can be averaged between the synthetic resin and the auxiliary substrate by providing the auxiliary substrate 97 having about the same temperature coefficient of expansion as the circuit substrate 91, whereby the difference in temperature coefficient of expansion between the synthetic resin and the circuit substrate can be reduced.

As a result, in the circuit module 90, warpage can be suppressed and the surface can be made flat.

However, in the circuit module 90 described above, the synthetic resin 94 covering the electronic components 92 and the auxiliary substrate 97 do not have shielding capability. Hence, the circuit module 90 is likely to be influenced by a change in the electromagnetic environment.

### SUMMARY OF THE INVENTION

A preferred embodiment of the present invention provides a circuit module including an auxiliary substrate where the circuit module in the auxiliary substrate covering electronic components has shielding capability.

To solve the above-described problems, preferred embodiments of the present invention provide a circuit module configured as follows.

A circuit module according to a preferred embodiment of the present invention includes: a circuit substrate; a plurality of electronic components mounted on one main surface of the circuit substrate; an auxiliary substrate arranged on the one main surface side of the circuit substrate on which the electronic components are mounted; and an insulating resin arranged between the circuit substrate and the auxiliary substrate in such a manner so as to cover the electronic components. The auxiliary substrate includes a base material layer having shielding capability, and the base material layer is connected to a ground electrode of the circuit substrate through an electronic component covered by the insulating resin.

With the configuration described above, by providing the auxiliary substrate having shielding capability so as to cover the mounted electronic components, the circuit module significantly reduces or prevents an influence from a change in the electromagnetic environment.

In the circuit module according to a preferred embodiment of the present invention, the base material layer preferably includes a cutout portion defined therein directly above at least one of the electronic components.

With the configuration described above, in the circuit module, by cutting out a portion of the base material layer directly above an electronic component which suffers from characteristics degradation as a result of being close to the base material layer with shielding capability, the characteristics degradation can be avoided.

In the circuit module according to a preferred embodiment of the present invention, preferably, the auxiliary substrate includes an electrode pattern arranged on the circuit substrate side of the base material layer and at least one passive device is made of the electrode pattern.

With the configuration described above, in the circuit module, the electrode pattern arranged on the circuit substrate side of the base material layer can be made to have the characteristics of a device having inductance or capacitance, enabling the adjustment of the circuit module characteristics, a reduction in the number of mounted components, and a reduction in the size of the circuit module.

In the circuit module according to a preferred embodiment of the present invention, preferably, the auxiliary substrate includes an electrode pattern arranged on a side of the base material layer opposite the circuit substrate side of the base material layer and at least one passive device is made of the electrode pattern.

With the configuration described above, in the circuit module, the electrode pattern arranged on a side of the base material layer opposite to the circuit substrate side of the base material layer can be made to have the characteristics of an antenna, enabling contribution to a reduction in the number of antenna components and a reduction in the size of the circuit module.

In the circuit module according to a preferred embodiment of the present invention, preferably, the auxiliary substrate is in contact with a top surface of an electronic component that is the tallest among the plurality of electronic components mounted on the circuit substrate.

In this manner, when the auxiliary substrate is made to contact a top surface of an electronic component that is the tallest among the plurality of electronic components, the distance between the circuit substrate and the auxiliary substrate can be minimized, such that the height of the circuit module can be significantly reduced.

In the circuit module according to a preferred embodiment of the present invention, for example, a column-shaped conductive element may be used as the electronic component connecting the base material layer to the ground electrode of the circuit substrate.

In this manner, when a conductive element is used to connect the base material layer to the ground electrode of the circuit substrate, freedom in the arrangement of other electronic components on the circuit substrate is increased. In other words, the arrangement of other electronic components is not restricted due to connection of the base material layer to the ground electrode, and other electronic components can be freely arranged in any location on the circuit substrate. When the terminal electrodes of a general electronic component including terminal electrodes at both ends thereof are used for the connection of the base material layer to the ground electrode, a connection material, such as solder, may adhere to the surface of portions of the component other than the terminal electrodes, so as to cause a problem such as short circuiting between two terminal electrodes. However, such a problem does not occur when the conductive element is used.

According to preferred embodiments of the present invention, an electromagnetically stable circuit module can be obtained by making an auxiliary substrate have also a shielding effect.

The above and other elements, features, steps, characteristics and advantages of the present invention will become more apparent from the following detailed description of the preferred embodiments with reference to the attached drawings.

### BRIEF DESCRIPTION OF THE DRAWINGS

FIGS. 1A-1C are diagrams illustrating a circuit module according to a first preferred embodiment of the present invention.

FIGS. 2A and 2B are diagrams illustrating a circuit module according to a modification of the first preferred embodiment of the present invention.

FIG. 3 is a diagram illustrating a circuit module according to a second preferred embodiment of the present invention.

FIG. 4 is a diagram illustrating a circuit module according to a third preferred embodiment of the present invention.

FIG. 5 is a diagram illustrating a circuit module according to a fourth preferred embodiment of the present invention.

FIG. 6 is a sectional view of an existing circuit module.

### DETAILED DESCRIPTION OF THE PREFERRED EMBODIMENTS

Hereinafter, preferred embodiments of the present invention will be described in detail with reference to the drawings.

### First Preferred Embodiment

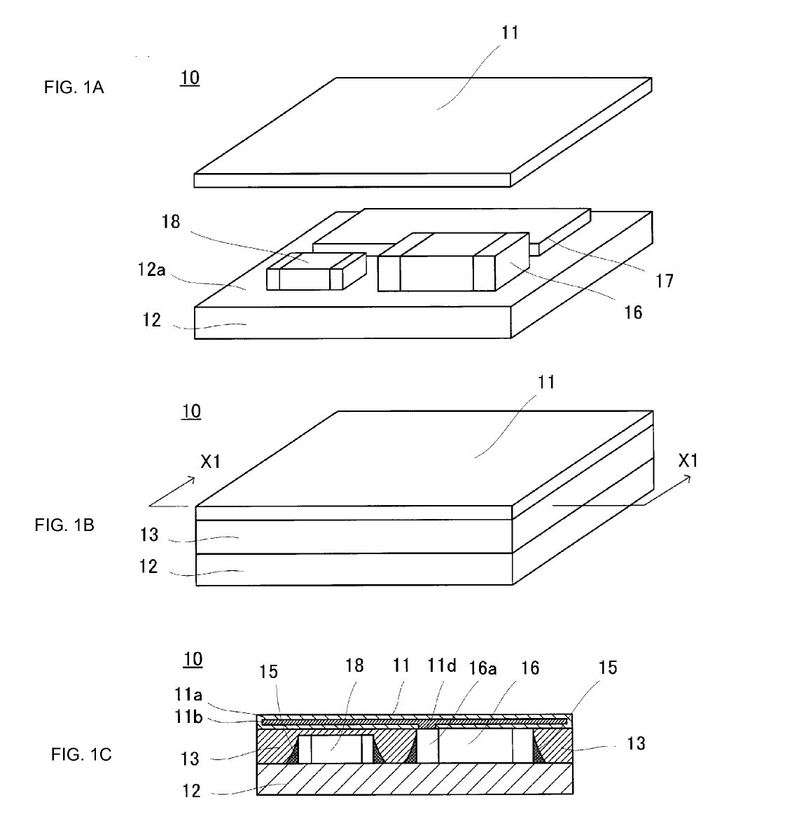

FIG. 1A is an exploded perspective view of a circuit module 10 of the present preferred embodiment (in which, for example, an insulating resin 13 is not illustrated) and FIG. 1B is an external perspective view.

FIG. 1C is a sectional view taken along X1-X1 in FIG. 1B.

Referring to FIGS. 1A-1C, for example, the circuit module 10 of the present preferred embodiment preferably includes a circuit substrate 12 made of, for example, a ceramic or a glass epoxy resin, electronic components 16, 17, and 18, such as, for example, a capacitor, a resistor, a filter, an inductor, an IC, etc. mounted on one main surface 12a of the circuit substrate 12 using, for example, solder 15, and an insulating resin 13 covering the electronic components. Further, the circuit module 10 preferably includes, on the insulating resin 13 thereof, an auxiliary substrate 11 which is a laminate made of a base material layer 11b with shielding capability and an insulating material 11a, such as a ceramic or a glass epoxy resin. The auxiliary substrate 11, when compared with the insulating resin 13, has a temperature coefficient of expansion that is sufficiently close to the temperature coefficient of expansion of the circuit substrate 12.

As illustrated in FIG. 1C, the base material layer 11b included in the auxiliary substrate 11 is preferably surrounded by the layer of the insulating material 11a, and the layer of the insulating material 11a has a non-provided portion through which the base material of the base material layer 11b is exposed to the outside, such that an exposed portion 11d is formed. The base material layer 11b is connected, at the exposed portion 11d, to a ground terminal 16a of the electronic component 16 which is the tallest among the electronic components described above. As a result, the base material layer 11b is electrically connected to the ground electrode of the circuit substrate and grounded, so as to produce a shielding effect. Note that the base material layer 11b is preferably made of, for example, a metal such as Cu or Ag and is defined by an electrode within the ceramic multilayer substrate or the multilayer substrate made of, for example, a glass epoxy resin. The exposed portion 11d is made of a via hole defined in the ceramic or resin multilayer substrate filled with a conductive material such as, for example, conductive paste.

Various types of stress are imposed on a circuit module from the outside, through a change in the surrounding environment during the manufacturing process and actual usage of the electronic apparatus, and the stress continues to accumulate within the circuit module. Specifically, stress caused by a difference in temperature coefficient of expansion among the members included in the circuit module may result in a serious reliability problem.

With the configuration described above, as a result of providing the auxiliary substrate 11 having a temperature coefficient of expansion about the same as that of the circuit substrate 12, stress accumulated between the insulating resin and the circuit substrate can be also dispersed to the auxiliary substrate 11 side.

Further, since the auxiliary substrate of the circuit module 10 includes a base material layer having shielding capability, even when the electromagnetic environment changes, the circuit module 10 can preferably keep of substantially keep a stable operation without being influenced by the change.

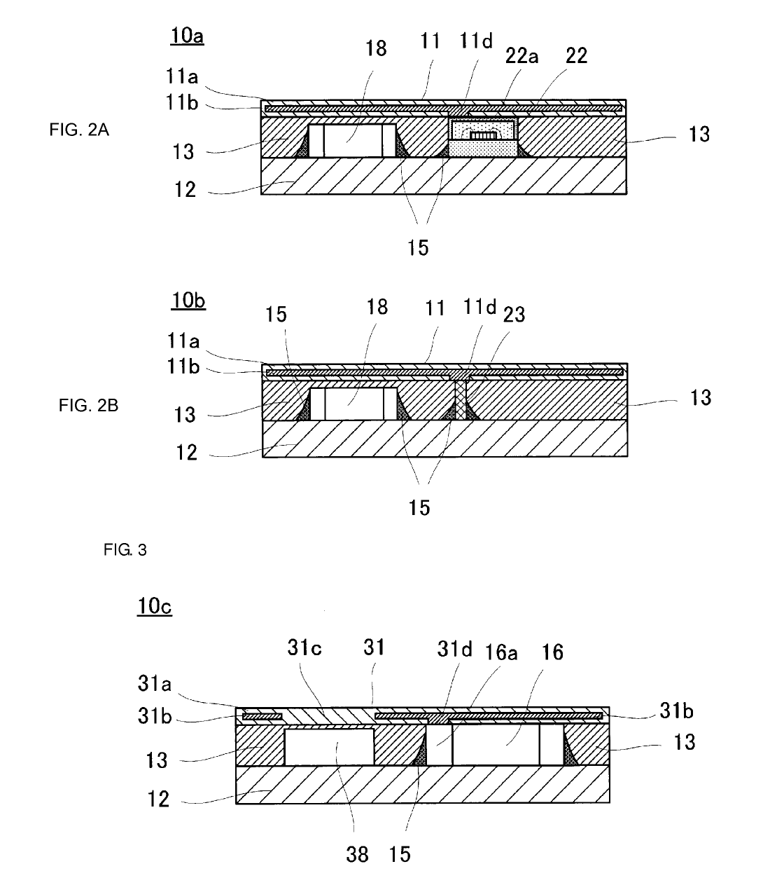

Modifications of the present preferred embodiment include the following, for example. Referring to FIG. 2A, a circuit module 10a may include a configuration in which the base material layer 11b having shielding capability is connected to an electronic component so as to be connected to the top surface of a grounded metal case 22a of a metal-case-equipped electronic component 22. Alternatively, as illustrated in FIG. 2B, a circuit module 10b may include a configuration in which a column-shaped conductive element 23 connected to the ground electrode of the circuit substrate is provided and the base material layer 11b having shielding capability is electrically connected to the conductive element 23. The conductive element 23 is made of only a conductive material and is, for example, a metal conductor or a member having a configuration in which a metal layer is defined so as to surround a column-shaped member made of a resin. The resistance, capacitance, and inductance of the conductive element 23 are approximately zero. In the manufacturing process, the conductive element is treated like an electronic component having other electric characteristics. This conductive element is illustrated as an example electronic component in the present specification.

### Second Preferred Embodiment

FIG. 3 is a sectional view of a circuit module 10c corresponding to a second preferred embodiment of the present invention.

The circuit module 10c of the present preferred embodiment preferably uses an auxiliary substrate 31 instead of the auxiliary substrate 11 of the circuit module 10 of the first preferred embodiment. The auxiliary substrate 31 preferably includes an insulating material 31a and a base material layer 31b having shielding capability, and the base material layer 31b includes a cutout portion 31c defined therein directly above an electronic component 38. The base material layer 31b is preferably connected to a ground terminal 16a of the tallest electronic component 16 in an exposed portion 31d where the base material layer 31b is exposed, and is grounded.

An electronic component, depending on its type and structure, may be influenced by the base material layer having shielding capability that is included in the auxiliary substrate, resulting in characteristics degradation, when the distance between the auxiliary substrate and the electronic component is decreased. The influence of the base material layer includes parasitic capacitance generated between the base material layer and the external electrodes or internal electrodes of the electronic component. Further, an electronic component, such as a coil, a coupler, or a filter, which utilizes propagation of an electromagnetic field generated by the internal wiring of the component may have distorted characteristics due to the propagation being significantly reduced or prevented by the base material layer.

With the configuration described above, by cutting out the base material layer directly above an electronic component that is likely to be influenced by the base material layer having shielding capability, the influence is avoided and characteristics degradation is significantly reduced or prevented.

### Third Preferred Embodiment

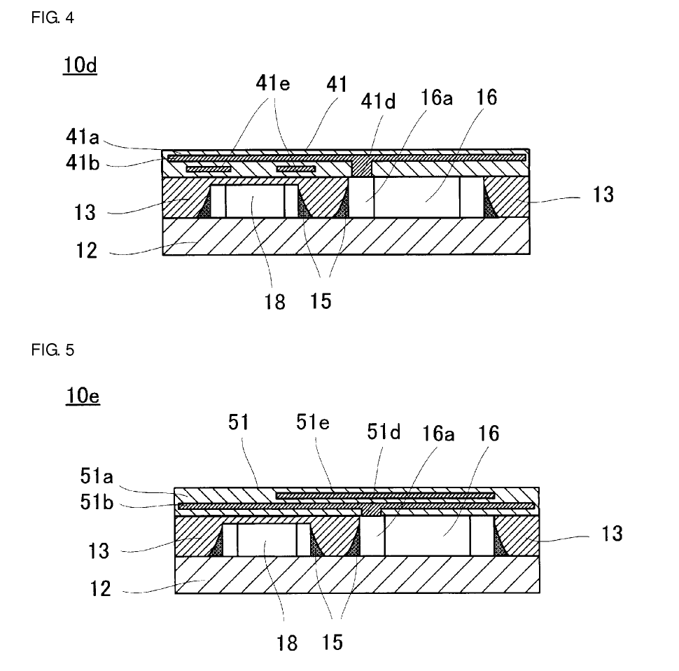

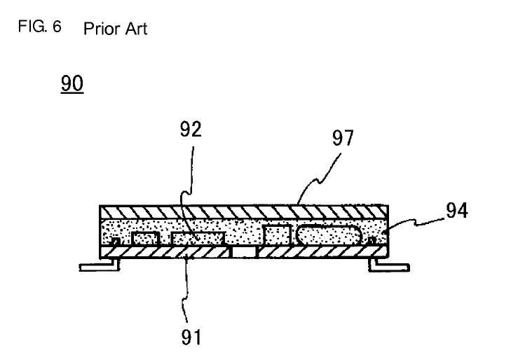

FIG. 4 is a sectional view of a circuit module 10d of a third preferred embodiment of the present invention.

The circuit module 10d of the present preferred embodiment preferably uses, instead of the auxiliary substrate 11 of the circuit module 10 of the first preferred embodiment, an auxiliary substrate 41 including an insulating material 41a, a base material layer 41b having shielding capability, and electrode patterns 41e provided on the circuit substrate 12 side of the base material layer 41b. The base material layer 41b is preferably connected to the ground terminal 16a of the tallest electronic component 16 in an exposed portion 41d where the base material layer 41b is exposed, and is grounded.

With the configuration described above, the electrode patterns 41e of the auxiliary substrate 41 can be made to have the characteristics of a passive device having inductance or capacitance, so as to contribute to the adjustment of the circuit module characteristics, a reduction in the number of mounted components, and a reduction in the size of the circuit module. Although not illustrated, a non-limiting example of a preferred method of providing an electrical connection in this device is forming a wiring pattern within the auxiliary substrate and preferably connecting the device to a wiring pattern of the circuit substrate 12 using, for example, a column-shaped conductive element such as, for example, the one illustrated in FIG. 2B.

### Fourth Preferred Embodiment

FIG. 5 is a sectional view of a circuit module 10e of a fourth preferred embodiment of the present invention.

The circuit module 10e of the present preferred embodiment preferably includes, instead of the auxiliary substrate 11 of the circuit module 10 of the first preferred embodiment, an auxiliary substrate 51 including an insulating material 51a, a base material layer 51b having shielding capability, and an electrode pattern 51e provided on a side of the base material layer 51b opposite to the circuit substrate 12 side of the base material layer 51b. The base material layer 51b is connected to the ground terminal 16a of the tallest electronic component 16 in an exposed portion 51d where the base material layer 51b is exposed, and is grounded.

With the configuration described above, the electrode pattern 51e within the auxiliary substrate 51 can be made to have the characteristics of an antenna as a passive device, enabling contribution to a reduction in the number of antenna components and a reduction in the size of the circuit module. Although not illustrated, a non-limiting example of a method of electrical connection of this device is forming a wiring pattern within the auxiliary substrate and preferably connecting the device to the circuit substrate 12 using, for example, a column-shaped conductive element such as, for example, the one illustrated in FIG. 2B.

The number of layers, materials of the layers, and configuration of each of the auxiliary substrates described in the preferred embodiments above are not limited to those described above. For example, by using a material having a large buffering effect as part of the material, stress accumulated in the connection portion between an electronic component and the auxiliary substrate can be reduced. Further, the height of the circuit module can be reduced by providing a recess or a through hole in the auxiliary substrate and making the tallest electronic component fit into the recess or through hole.

While preferred embodiments of the present invention and modifications thereof have been described above, it is to be understood that variations and further modifications will be apparent to those skilled in the art without departing from the scope and spirit of the present invention. The scope of the present invention, therefore, is to be determined solely by the following claims.

What is claimed is:

1. A circuit module comprising:
a circuit substrate;
a plurality of electronic components mounted on one main surface of the circuit substrate;
an auxiliary substrate arranged on the one main surface side of the circuit substrate on which the electronic components are mounted; and
an insulating resin arranged between the circuit substrate and the auxiliary substrate so as to cover the electronic components; wherein
the auxiliary substrate includes a base material layer having a shielding characteristic; and
the base material layer is connected to a ground electrode of the circuit substrate through an electronic component covered by the insulating resin.

2. The circuit module according to claim 1, wherein the base material layer includes a cutout portion defined therein directly above at least one of the electronic components.

3. The circuit module according to claim 1, wherein
the auxiliary substrate includes an electrode pattern arranged on a circuit substrate side of the base material layer; and
at least one passive device is made of the electrode pattern.

4. The circuit module according to claim 1, wherein
the auxiliary substrate includes an electrode pattern arranged on a side of the base material layer opposite to a circuit substrate side of the base material layer; and
at least one passive device is defined by the electrode pattern.

5. The circuit module according to claim 1, wherein the auxiliary substrate is in contact with a top surface of an electronic component that is the tallest among the plurality of electronic components mounted on the circuit substrate.

6. The circuit module according to claim 1, wherein a column-shaped conductive element is arranged as the electronic component connecting the base material layer to the ground electrode of the circuit substrate.

7. The circuit module according to claim 1, wherein the plurality of electronic components include at least one of a capacitor, a resistor, a filter, an inductor, and an integrated circuit.

8. The circuit module according to claim 1, wherein the electronic component covered by the insulating resin includes a grounded metal case electrically connected to the ground electrode.

9. The circuit module according to claim 1, wherein the base material layer is made of Cu or Ag and is defined by an electrode within the auxiliary substrate, which is made of a glass epoxy resin.

10. The circuit module according to claim 5, wherein the base material layer includes a cutout portion defined therein directly above the top surface of an electronic component that is the tallest among the plurality of electronic components mounted on the circuit substrate.

11. The circuit module according to claim 10, wherein the cutout portion includes a via hole defined in the auxiliary substrate filled with a conductive material.

12. The circuit module according to claim 11, wherein the conductive material is a conductive paste.

13. The circuit module according to claim 3, wherein the at least one passive device is an inductor and/or a capacitor.

14. The circuit module according to claim 4, wherein the at least one passive device is an antenna.

15. The circuit module according to claim 2, wherein
the auxiliary substrate includes an electrode pattern arranged on a circuit substrate side of the base material layer; and
at least one passive device is made of the electrode pattern.

16. The circuit module according to claim 15, wherein the at least one passive device is an inductor and/or a capacitor.

17. The circuit module according to claim 2, wherein
the auxiliary substrate includes an electrode pattern arranged on a side of the base material layer opposite to a circuit substrate side of the base material layer; and
at least one passive device is defined by the electrode pattern.

18. The circuit module according to claim 17, wherein the at least one passive device is an antenna.

19. The circuit module according to claim 2, wherein the auxiliary substrate is in contact with a top surface of an electronic component that is the tallest among the plurality of electronic components mounted on the circuit substrate.

20. The circuit module according to claim 2, wherein a column-shaped conductive element is arranged as the electronic component connecting the base material layer to the ground electrode of the circuit substrate.
